(19) United States
(12) Patent Application Publication
(10) Pub. No.: US 2022/0238827 A1
(43) Pub. Date: Jul. 28, 2022

(54) ELECTROLUMINESCENT ELEMENT, DISPLAY PANEL AND DISPLAY DEVICE

(71) Applicant: BOE Technology Group Co., Ltd., Beijing (CN)

(72) Inventor: Yang LIU, Beijing (CN)

(21) Appl. No.: 17/486,674

(22) Filed: Sep. 27, 2021

(30) Foreign Application Priority Data
Jan. 28, 2021 (CN) 202110120463.1

(51) Int. Cl. H01L 51/50

(52) U.S. Cl. CPC H01L 51/5004; H01L 51/5028; H01L 51/5056; H01L 51/0072; H01L 2251/5384; H01L 2251/552; H01L 51/5072

(57) ABSTRACT

The present disclosure provides an electroluminescent element, a display panel and a display device. The electroluminescent element includes an electron transport layer, a green light-emitting layer, and a hole transport layer laminated one on another. The green light-emitting layer includes a hole-type host material, an electron-type host material, and a green guest light-emitting material.

### CROSS-REFERENCE TO RELATED APPLICATION

The present application claims a priority of the Chinese patent application No. 202110120463.1, filed on Jan. 28, 2021, which is incorporated herein by reference in its entirety.

### TECHNICAL FIELD

The present disclosure relates to the field of display technology, in particular to an electroluminescent element, a display panel and a display device.

### BACKGROUND

Organic Light-Emitting Diode (OLED), as a new-generation light-emitting display technology for liquid crystal display, has been widely used in various mobile phones and wearable devices due to such advantages as wide viewing angle, high contrast, being rich in colors, and flexible display, and it has a good prospect.

For the OLED, usually the electroluminescence is achieved through carrier injection and recombination. A specific light-emission principle will be described as follows. Under the effect of an electric field, holes generated by an anode and electrons generated by a cathode move to a light-emitting layer through a hole transport layer and an electron transport layer respectively. When the holes and the electrons meet at the light-emitting layer, energy excitons are generated, so as to excite light-emitting molecules to finally generate visible light.

However, for a conventional electroluminescent element, there exists such a defect as low green light luminous efficiency or a short service life.

### SUMMARY

An object of the present disclosure is to provide an electroluminescent element, a display panel and a display device, so as to solve the above-mentioned problem.

In one aspect, the present disclosure provides in some embodiments an electroluminescent element, including an electron transport layer, a green light-emitting layer and a hole transport layer laminated one on another. The green light-emitting layer includes a hole-type host material, an electron-type host material and a green guest light-emitting material. When a ratio of hole mobility of the hole-type host material to electron mobility of the electron-type host material is not greater than 1:1, a ratio of a first energy level difference to a second energy level difference is not greater than 1:1. When the ratio of the hole mobility of the hole-type host material to the electron mobility of the electron-type host material is not less than 1:1, the ratio of the first energy level difference to the second energy level difference is not less than 1:1. The first energy level difference is a difference between a Highest Occupied Molecular Orbital (HOMO) energy level of the hole-type host material and an HOMO energy level of the green guest light-emitting material, and the second energy level difference is a difference between a Lowest Unoccupied Molecular Orbital (LUMO) energy level of the electron-type host material and an LUMO energy level of the green guest light-emitting material.

In a possible embodiment of the present disclosure, the ratio of the hole mobility of the hole-type host material to the electron mobility of the electron-type host material is not less than 1:100 and not greater than 100:1.

In a possible embodiment of the present disclosure, the hole mobility of the hole-type host material is not less than 1×10⁻⁸ cm²/v·s and not more than 1×10⁻⁴ cm²/v·s; or the electron mobility of the electron-type host material is not less than 1×10⁻⁸ cm²/v·s and not more than 1×10⁻⁴ cm²/v·s.

In a possible embodiment of the present disclosure, the hole mobility of the hole-type host material is not less than 1×10⁻⁸ cm²/v·s and not more than 1×10⁻⁴ cm²/v·s, and the electron mobility of the electron-type host material is not less than 1×10⁻⁸ cm²/v·s and not more than 1×10⁻⁴ cm²/v·s.

In a possible embodiment of the present disclosure, the HOMO energy level of the hole-type host material is not less than 5.3 eV and not more than 5.8 eV; or the HOMO energy level of the electron-type host material is not less than 5.5 eV and not more than 6.2 eV.

In a possible embodiment of the present disclosure, the HOMO energy level of the hole-type host material is not less than 5.3 eV and not more than 5.8 eV, and the HOMO energy level of the electron-type host material is not less than 5.5 eV and not more than 6.2 eV.

In a possible embodiment of the present disclosure, the LUMO energy level of the hole-type host material is not less than 2.0 eV and not more than 2.5 eV; or the LUMO energy level of the electron-type host material is not less than 2.2 eV and not more than 2.7 eV.

In a possible embodiment of the present disclosure, the LUMO energy level of the hole-type host material is not less than 2.0 eV and not more than 2.5 eV, and the LUMO energy level of the electron-type host material is not less than 2.2 eV and not more than 2.7 eV.

In a possible embodiment of the present disclosure, the HOMO energy level of the green guest light-emitting material is not less than 4.8 eV and not more than 5.2 eV; or the LUMO energy level of the green guest light-emitting material is not less than 2.4 eV and not more than 2.8 eV.

In a possible embodiment of the present disclosure, the HOMO energy level of the green guest light-emitting material is not less than 4.8 eV and not more than 5.2 eV, and the LUMO energy level of the green guest light-emitting material is not less than 2.4 eV and not more than 2.8 eV.

In a possible embodiment of the present disclosure, a mass ratio of the hole-type host material to the electron-type host material is not less than 1:1 and not more than 4:1, and the ratio of the first energy level difference to the second energy level difference is not less than 1:4 and not more than 1:1.

In a possible embodiment of the present disclosure, a ratio of the hole mobility of the hole-type host material to the electron mobility of the electron-type host material is not less than 1:100 and not more than 1:1.

In a possible embodiment of the present disclosure, a mass ratio of the hole-type host material to the electron-type host material is not less than 1:4 and not more than 1:1, and the ratio of the first energy level difference to the second energy level difference is not less than 1:1 and not more than 4:1.

In a possible embodiment of the present disclosure, the ratio of the hole mobility of the hole-type host material to the electron mobility of the electron-type host material is not less than 1:1 and not more than 100:1.

In a possible embodiment of the present disclosure, the hole-type host material includes: a 9,9′-3,3′-bicarbazole unit containing a first substituent, and the first substituent includes at least one of a substituted or unsubstituted C6 to C30 aryl group, a substituted or unsubstituted C2 to C30 heterocyclic group, and a substituted or unsubstituted C6 to C30 arylamine group.

In a possible embodiment of the present disclosure, the electron-type host material includes an azine unit containing a second substituent, and the second substituent includes at least one of hydrogen, deuterium, a substituted or unsubstituted C1 to C20 alkyl group, a substituted or unsubstituted C6 to C30 aryl group, a substituted or unsubstituted C2 to C30 heterocyclic group, a substituted or unsubstituted nitrile group, a substituted or unsubstituted isonitrile group, a substituted or unsubstituted hydroxyl group, and a substituted or unsubstituted thiol group.

In a possible embodiment of the present disclosure, the green guest light-emitting material includes a diphenylpyridine iridium metal complex containing a third substituent, and the third substituent includes at least one of hydrogen, an alkyl group, an alkenyl group, an alkynyl group, a heteroalkyl group, an alkenyl group, an alkynyl group, a heteroalkyl group, aryl group, a heteroaryl group, and an aralkyl group.

In another aspect, the present disclosure provides in some embodiments a display panel, including a cathode layer, an anode layer and the above-mentioned electroluminescent element. The cathode layer is located at a side of the electron transport layer away from the green light-emitting layer in the electroluminescent element, and the anode layer is located at a side of the hole transport layer away from the green light-emitting layer in the electroluminescent element.

In yet another aspect, the present disclosure provides in some embodiments a display device including the above-mentioned electroluminescent element.

In still yet another aspect, the present disclosure provides in some embodiments a display device including the above-mentioned display panel.

### BRIEF DESCRIPTION OF THE DRAWINGS

The present disclosure will be described hereinafter in more details in conjunction with the drawings.

FIG. 1 is a schematic view of an electroluminescent element according to one embodiment of the present disclosure;

FIG. 2 is a schematic view of a green light-emitting layer including a hole-type host material, an electron-type host material and a green guest light-emitting material according to one embodiment of the present disclosure;

FIG. 3 is a schematic view of a display panel according to one embodiment of the present disclosure;

FIG. 4 shows a chemical formula of P1 according to one embodiment of the present disclosure;

FIG. 5 shows a chemical formula of P2 according to one embodiment of the present disclosure;

FIG. 6 shows a chemical formula of N1 according to one embodiment of the present disclosure;

FIG. 7 shows a chemical formula of N2 according to one embodiment of the present disclosure;

FIG. 8 shows a chemical formula of GD according to one embodiment of the present disclosure; and

FIG. 9 is a diagram showing light-emitting effects at an exciton recombination region of Example 1 and Comparative Example 1 according to one embodiment of the present disclosure.

### REFERENCE SIGN LIST

100 electroluminescent element
110 green light-emitting layer
111 hole-type host material
112 electron-type host material
113 green guest light-emitting material
120 electron transport layer
130 hole transport layer
200 display panel
210 cathode layer
220 anode layer

### DETAILED DESCRIPTION

The present disclosure will be described hereinafter in conjunction with the embodiments and the drawings. Identical or similar reference numbers in the drawings represent an identical or similar element or elements having an identical or similar function. In addition, the detailed description about any know technology, which is unnecessary to the features in the embodiments of the present disclosure, will be omitted. The following embodiments are for illustrative purposes only, but shall not be used to limit the scope of the present disclosure.

Unless otherwise defined, any technical or scientific term used herein shall have the common meaning understood by a person skilled in the art. It should be further appreciated that, any term defined in a commonly-used dictionary shall be understood as having the meaning in conformity with that in the related art, and shall not be interpreted idealistically or extremely, unless clearly defined.

Unless otherwise defined, such words as “one” or “one of” are merely used to represent the existence of at least one member, rather than to limit the number thereof. Such words as “include” or “including” intend to indicate that there are the features, integers, steps, operations, elements and/or assemblies, without excluding the existence or addition of one or more other features, integers, steps, operations, elements, assemblies and/or combinations thereof. In the case that one element is connected or coupled to another element, it may be directly connected or coupled to the other element, or an intermediate element may be arranged therebetween. At this time, the element may be connected or coupled to the other element in a wireless manner. In addition, the expression “and/or” is used to indicate the existence of all or any one of one or more of listed items, or combinations thereof

At first, several terms involved in the embodiments of the present disclosure will be introduced hereinafter.

HOMO: Highest Occupied Molecular Orbital, that is, an orbital with an occupied electron at a highest energy level.

LUMO: Lowest Unoccupied Molecular Orbital, that is, an orbital without an occupied electron at a lowest energy level.

Energy level: electrons only move on specific, discrete orbits outside a nucleus, the electrons on each orbital have discrete energy values, and these energy values are energy levels.

It is found through research that, in mass-produced OLED elements, a green light-emitting element is a phosphorescent element, and a light-emitting layer is made of a premixed material. The premixed material includes a hole-type host material, an electron-type host material and a green guest light-emitting material.

On one hand, hole mobility of the hole-type host material is lower than electron mobility of the electron-type host material, so an exciton recombination region of the green light-emitting element is located at a side of a green light-emitting layer close to a hole transport layer. A strong triplet exciton annihilation effect occurs due to a high exciton concentration, thereby luminous efficiency of the element is deteriorated.

On the other hand, a difference AHOMO between an HOMO energy level of the hole-type host material and an HOMO energy level of the green guest light-emitting material is greater than a difference ALUMO between an LUMO energy level of the electron-type host material and an LUMO energy level of the green guest light-emitting material, so the exciton recombination region of the green light-emitting element is located at the side of the green light-emitting layer close to the hole transport layer. Identically, the strong triplet exciton annihilation effect occurs due to the high exciton concentration, thereby the luminous efficiency of the element is deteriorated.

It is also found that, in the premixed material, the hole-type host material is used to transfer holes, and the electron-type host material is used to transfer electrons. Due to the energy level difference between the green guest light-emitting material and each of the hole-type host material and the electron-type host material, the green guest light-emitting material is equivalent to a trap for the holes and electrons. Due to the restraint in a structure of the hole-type host material itself (for example, a carbazole-type structure), the HOMO energy level of the hole-type host material does not change greatly, so it is able to adjust a hole-electron balance of the green light-emitting layer by adjusting a resistance to the electrons, and enlarge the exciton recombination region, thereby to improve the luminous efficiency of the green light-emitting element and prolong its service life.

An object of the present disclosure is to provide an electroluminescent element, a display panel and a display device, so as to solve the above-mentioned problems in the related art.

The technical solutions of the present disclosure and how to solve the above-mentioned problems through the technical solutions will be described hereinafter in details in conjunction with the embodiments.

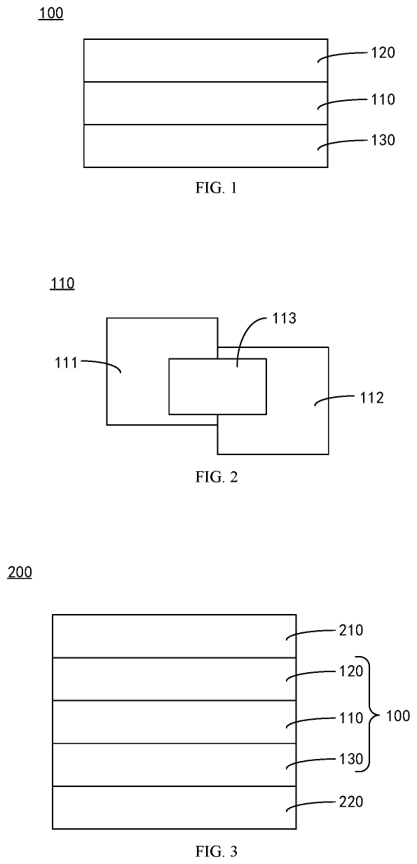

The present disclosure provides in some embodiments an electroluminescent element 100 which, as shown in FIG. 1, includes an electron transport layer 120, a green light-emitting layer 110 and a hole transport layer 130 laminated one on another.

As shown in FIG. 2, the green light-emitting layer 110 includes a hole-type host material 111, an electron-type host material 112, and a green guest light-emitting material 113.

When a ratio of hole mobility of the hole-type host material 111 to electron mobility of the electron-type host material 112 is not greater than 1:1, a ratio of a first energy level difference to a second energy level difference is not greater than 1:1.

When the ratio of the hole mobility of the hole-type host material 111 to the electron mobility of the electron-type host material 112 is not less than 1:1, the ratio of the first energy level difference to the second energy level difference is not less than 1:1.

The first energy level difference is a difference between an HOMO energy level of the hole-type host material 111 and an HOMO energy level of the green guest light-emitting material 113. The second energy level difference is a difference between an LUMO energy level of the electron-type host material 112 and an LUMO energy level of the green guest light-emitting material 113.

According to the embodiments of the present disclosure, the ratio of the hole mobility to the electron mobility and the energy level difference ratio of the green light-emitting layer 110 are adjusted to control a balance between the hole transport and the electron transport of the green light-emitting layer 110, so that an exciton recombination region moves from a side of the green light-emitting layer close to the hole transport layer 130 to an interior of the green light-emitting layer. As a result, it is able to not only weaken a triplet exciton annihilation effect but also enlarge the exciton recombination region, thereby to improve the luminous efficiency as well as a service life of the electroluminescent element.

In a possible embodiment of the present disclosure, the ratio of the hole mobility to the electron mobility of the green light-emitting layer is not less than 1:100 and not more than 100:1.

In the embodiments of the present disclosure, the ratio of the hole mobility to the electron mobility of the green light-emitting layer 110 in the electroluminescent element 100 is adjusted to be not less than 1:100 and not more than 100:1 to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

It is necessary to adjust the balance between the hole transport and the electron transport of the green light-emitting layer 110 to improve the luminous efficiency and the service life, so the electroluminescent element 100 will be implemented as follows.

In the embodiments of the present disclosure, as shown in FIG. 2, the green light-emitting layer 110 includes, but not limited to, the hole-type host material 111, the electron-type host material 112 and the green guest light-emitting material 113.

In some embodiments of the present disclosure, the hole mobility of the hole-type host material 111 is not less than 1×10⁻⁸ square cm²/v·s (centimeter per volt per second) and not more than 1×10⁻⁴ cm²/v·s.

In the embodiments of the present disclosure, when the hole mobility of the green light-emitting layer 110 is adjusted to be not less than 1×10⁻⁸ cm²/v·s and not more than 1×10⁻⁴ cm²/v·s, it is able to control the balance between the hole transport and between electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the electron mobility of the electron-type host material 112 is not less than 1×10⁻⁸ square cm²/v·s and not more than 1×10⁻⁴ cm²/v·s.

In the embodiments of the present disclosure, when the electron mobility of the electron-type host material 112 is adjusted to be not less than 1×10⁻⁸ square cm²/v·s and not more than 1×10⁻⁴ cm²/v·s, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the hole mobility of the hole-type host material 111 is not less than 1×10⁻⁸ cm²/v·s and not more than 1×10⁻⁴ cm²/v·s, and the electron mobility of the electron-type host material 112 is not less than 1×10⁻⁸ cm²/v·s and not more than 1×10⁻⁴ cm²/v·s.

In the embodiments of the present disclosure, when the hole mobility of the hole-type host material 111 is adjusted to be not less than 1×10⁻⁸ cm²/v·s and not more than 1×10⁻⁴ cm²/v·s and the electron mobility of the electron-type host material 112 is adjusted to be not less than 1×10⁻⁸ cm²/v·s and not more than 1×10⁻⁴ cm²/v·s, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In a possible embodiment of the present disclosure, the hole mobility of the hole-type host material 111 is 2.8×10⁻⁷ cm²/v·s, and the electron mobility of the electron-type host material 112 is 7.6×10⁻⁶ cm²/v·s. Based on this, it is able to facilitate the movement of the exciton recombination region from the side of the green light-emitting layer 110 close to the hole transport layer 130 to the interior of the green light-emitting layer 110. As a result, it is able to not only weaken the triplet exciton annihilation effect but also enlarge the exciton recombination region, thereby to improve the luminous efficiency as well as the service life of the electroluminescent element.

It should be appreciated that, as mentioned hereinabove, the hole mobility of the hole-type host material 111 or the electron mobility of the electron-type host material 112 is adjusted through selecting a material with corresponding mobility.

Considering that the balance between the hole transport and the electron transport of the green light-emitting layer 110 is affected by the HOMO energy level of the hole-type host material 111 or the HOMO energy level of the electronic-type host material 112, the electroluminescent element 100 will be implemented as follows.

In some embodiments of the present disclosure, the HOMO energy level of the hole-type host material 111 is not less than 5.3 eV and not more than 5.8 eV.

In the embodiments of the present disclosure, when the HOMO energy level of the hole-type host material 111 is adjusted to be not less than 5.3 eV and not more than 5.8 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the HOMO energy level of the electron-type host material 112 is not less than 5.5 eV and not more than 6.2 eV.

In the embodiments of the present disclosure, when the HOMO energy level of the electron-type host material 112 is adjusted to be not less than 5.5 eV and not more than 6.2 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the HOMO energy level of the hole-type host material 111 is not less than 5.3 eV and not more than 5.8 eV, and the HOMO energy level of the electron-type host material 112 is not less than 5.5 eV and not more than 6.2 eV.

In the embodiments of the present disclosure, when the HOMO energy level of the hole-type host material 111 is adjusted to be not less than 5.3 eV and not more than 5.8 eV and the HOMO energy level of the electron-type host material 112 is adjusted to be not less than 5.5 eV and not more than 6.2 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

Considering that the balance between the hole transport and the electron transport of the green light-emitting layer 110 is affected by the LOMO energy level of the hole-type host material 111 or the LOMO energy level of the electronic-type host material 112, so the electroluminescent element 100 will be implemented as follows.

In some embodiments of the present disclosure, the LUMO energy level of the hole-type host material 111 is not less than 2.0 eV and not more than 2.5 eV.

In the embodiments of the present disclosure, when the LUMO energy level of the hole-type host material 111 is adjusted to be not less than 2.0 eV and not more than 2.5 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the LUMO energy level of the electron-type host material 112 is not less than 2.2 eV and not more than 2.7 eV.

In the embodiments of the present disclosure, when the LUMO energy level of the electron-type host material 112 is adjusted to be not less than 2.2 eV and not more than 2.7 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the LUMO energy level of the hole-type host material 111 is not less than 2.0 eV and not more than 2.5 eV, and the LUMO energy level of the electron-type host material 112 is not less than 2.2 eV and not more than 2.7 eV.

In the embodiments of the present disclosure, when the LUMO energy level of the hole-type host material 111 is adjusted to be not less than 2.0 eV and not more than 2.5 eV and the LUMO energy level of the electron-type host material 112 is adjusted to be not less than 2.2 eV and not more than 2.7 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

Considering that the balance between the hole transport and the electron transport of the green light-emitting layer 110 is affected by the HOMO energy level of the green guest light-emitting material 113 or the LOMO energy level of the green guest light-emitting material 113, the electroluminescent element 100 will be implemented as follows.

In some embodiments of the present disclosure, the HOMO energy level of the green guest light-emitting material 113 is not less than 4.8 eV and not more than 5.2 eV.

In the embodiments of the present disclosure, when the HOMO energy level of the green guest light-emitting material 113 is adjusted to be not less than 4.8 eV and not more than 5.2 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the LUMO energy level of the green guest light-emitting material 113 is not less than 2.4 eV and not more than 2.8 eV.

In the embodiments of the present disclosure, when the LUMO energy level of the green guest light-emitting material 113 is adjusted to be not less than 2.4 eV and not more than 2.8 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the HOMO energy level of the green guest light-emitting material 113 is not less than 4.8 eV and not more than 5.2 eV, and the LUMO energy level of the green guest light-emitting material is not less than 2.4 eV and not more than 2.8 eV.

In the embodiments of the present disclosure, when the HOMO energy level of the green guest light-emitting material 113 is adjusted to be not less than 4.8 eV and not more than 5.2 eV and the LUMO energy level of the green guest light-emitting material is adjusted to be not less than 2.4 eV and not more than 2.8 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

It should be appreciated that, in the above-mentioned embodiments of the present disclosure, the HOMO energy level of the semiconductor material o the LUMO energy level of the semiconductor material is adjusted through selecting a material with a corresponding HOMO energy level or LUMO energy level.

Considering that the balance between the hole transport and the electron transport of the green light-emitting layer 110 is affected by the ratio of the energy level difference between the green guest light-emitting material 113 and each of the hole-type host material 111 and the electron-type host material 112 in the green light-emitting layer 110, and a mass ratio of the hole-type host material 111 to the electron-type host material 112 in the green light-emitting layer 110, the electroluminescent element 100 will be implemented as follows.

In some embodiments of the present disclosure, a mass ratio of the hole-type host material 111 to the electron-type host material 112 is not less than 1:1 and not more than 4:1, and the ratio of the first energy level difference to the second energy level difference is not less than 1:4 and not more than 1:1.

In the embodiments of the present disclosure, when the mass ratio of the hole-type host material 111 to the electron-type host material 112 is adjusted to be not less than 1:1 and not more than 4:1 and the ratio of the first energy level difference to the second energy level difference is adjusted to be not less than 1:4 and not more than 1:1, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the ratio of the hole mobility of the hole-type host material 111 to the electron mobility of the electron-type host material 112 is not less than 1:100 and not more than 1:1. Under this condition, the mass ratio of the hole-type host material 111 to the electron-type host material 112 is not less than 1:1 and not more than 4:1, and the ratio of the first energy level difference to the second energy level difference is not less than 1:4 and not more than 1:1. The first energy level difference is a difference between the HOMO energy level of the hole-type host material 111 and the HOMO energy level of the green guest light-emitting material 113, and the second energy level difference is a difference between the LUMO energy level of the electron-type host material 112 and the LUMO energy level of the green guest light-emitting material 113.

In the embodiments of the present disclosure, under the condition that the hole mobility of the hole-type host material 111 to the electron mobility of the electron-type host material 112 is not less than 1:100 and not more than 1:1, the ratio of the first energy level difference to the second energy level difference is adjusted to be not less than 1:4 and not more than 1:1, and the mass ratio of the hole-type host material 111 to the electron-type host material 112 is adjusted not less than 1:1 and not more than 4:1, so as to facilitate the movement of the exciton recombination region from the side of the green light-emitting layer close to the hole transport layer 130 to the interior of the green light-emitting layer more advantageously. As a result, it is able to not only weaken the triplet exciton annihilation effect but also enlarge the exciton recombination region, thereby to improve the luminous efficiency as well as the service life of the electroluminescent element.

In some embodiments of the present disclosure, the HOMO energy level of the hole-type host material 111 is 5.45 eV, the LUMO energy level of the hole-type host material 111 is 2.15 eV, the HOMO energy level of the electron-type host material 112 is 5.62 eV, the LUMO energy level of the electron-type host material 112 is 2.33 eV, the HOMO energy level of the green guest light-emitting material 113 is 5.15 eV, the LUMO energy level of the green guest light-emitting material 113 is 2.72 eV, and the mass ratio of the hole-type host material 111 and the electron-type host material 112 is 3:2.

Based on the above, it is able to facilitate the movement of the exciton recombination region from the side of the green light-emitting layer 110 close to the hole transport layer 130 to the interior of the green light-emitting layer 110. As a result, it is able to not only weaken the triplet exciton annihilation effect but also enlarge the exciton recombination region, thereby to improve the luminous efficiency as well as the service life of the electroluminescent element.

In some embodiments of the present disclosure, the mass ratio of the hole-type host material 111 to the electron-type host material 112 is not less than 1:4 and not more than 1:1, and the ratio of the first energy level difference to the second energy level difference is not less than 1:1 and not more than 4:1.

In the embodiments of the present disclosure, when the mass ratio of the hole-type host material 111 to the electron-type host material 112 is adjusted to be not less than 1:1 and not more than 4:1 and the ratio of the first energy level difference to the second energy level difference is adjusted to be not less than 1:4 and not more than 1:1, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

In some embodiments of the present disclosure, the ratio of the hole mobility of the hole-type host material 111 to the electron mobility of the electron-type host material 112 is not less than 1:1 and not more than 100:1. Under this condition, the mass ratio of the hole-type host material 111 to the electron-type host material 112 is not less than 1:4 and not more than 1:1, and the ratio of the first energy level difference to the second energy level difference is not less than 1:1 and not more than 4:1.

In the embodiments of the present disclosure, under the condition that the hole mobility of the hole-type host material 111 to the electron mobility of the electron-type host material 112 is not less than 1:1 and not more than 100:1, the ratio of the first energy level difference to the second energy level difference is adjusted to be not less than 1:1 and not more than 4:1, and the mass ratio of the hole-type host material 111 to the electron-type host material 112 is adjusted not less than 1:4 and not more than 1:1, so as to facilitate the movement of the exciton recombination region from the side of the green light-emitting layer close to the hole transport layer 130 to the interior of the green light-emitting layer more advantageously. As a result, it is able to not only weaken the triplet exciton annihilation effect but also enlarge the exciton recombination region, thereby to improve the luminous efficiency as well as the service life of the electroluminescent element.

Based on the above, the hole-type host material 111, the electron-type host material 112 and the green guest light-emitting material 113 will be described as follows.

In a possible embodiment of the present disclosure, the hole-type host material 111 includes a 9,9′-3,3′-bicarbazole unit containing a first substituent, and the first substituent includes at least one of a substituted or unsubstituted C6 to C30 aryl group, a substituted or unsubstituted C2 to C30 heterocyclic group, and a substituted or unsubstituted C6 to C30 arylamine group.

In a possible embodiment of the present disclosure, the electron-type host material 112 includes an azine unit containing a second substituent, and the second substituent includes at least one of hydrogen, deuterium, a substituted or unsubstituted C1 to C20 alkyl group, a substituted or unsubstituted C6 to C30 aryl group, a substituted or unsubstituted C2 to C30 heterocyclic group, a substituted or unsubstituted nitrile group, a substituted or unsubstituted isonitrile group, a substituted or unsubstituted hydroxyl group, and a substituted or unsubstituted thiol group. In a possible embodiment of the present disclosure, substituents on the aforementioned various azine units can exist independently; adjacent substituents on the aforementioned azine units can also be connected to each other to form a cyclic structure.

In a possible embodiment of the present disclosure, the green guest light-emitting material 113 includes a diphenylpyridine iridium metal complex containing a third substituent, and the third substituent includes at least one of hydrogen, an alkyl group, an alkenyl group, an alkynyl group, a heteroalkyl group, an alkenyl group, an alkynyl group, a heteroalkyl group, aryl group, a heteroaryl group, and an aralkyl group.

It should be appreciated that, the term “substituted” means that at least one hydrogen of a substituent or compound is substituted by a corresponding group.

The term “hetero” means that at least one heteroatom is contained in one functional group and the rest are carbon. In a possible embodiment of the present disclosure, the heteroatom includes at least one of nitrogen, oxygen, sulfur, phosphorus, and silicon.

The term “aryl group” refers to a group containing at least one hydrocarbon aromatic moiety, and contains carbocyclic aromatic moieties connected by a single bond and a carbocyclic aromatic moiety fused directly or indirectly to provide a non-aromatic fused ring. The aryl group includes a monocyclic, polycyclic, or fused polycyclic (i.e., rings that share adjacent pairs of carbon atoms) functional group.

The term “heterocyclic group” refers to a cyclic compound containing at least one heteroatom selected from nitrogen, oxygen, sulfur, phosphorus, and silicon, with the rest being carbon, such as an aryl group, a cycloalkyl group, and a fused ring thereof or combination thereof. When the heterocyclic group is a fused ring, the entire ring or each ring of the heterocyclic group may contain at least one heteroatom.

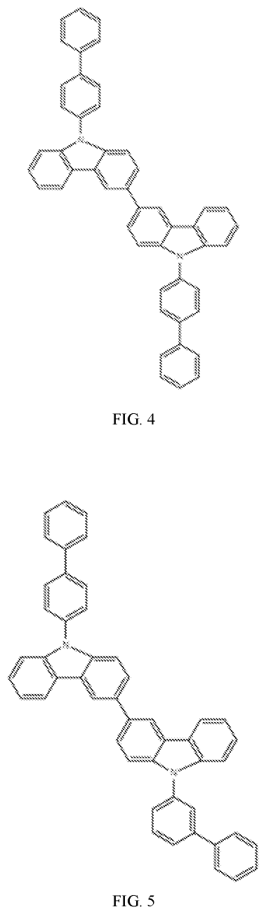

Based on a same inventive concept, the present disclosure further provides in some embodiments a display panel 200 which, as shown in FIG. 3, includes, but not limited to, a cathode layer 210, an anode layer 220 and the above-mentioned electroluminescent element 100.

The cathode layer 210 is located at a side of the electron transport layer 120 away from the green light-emitting layer 110 in the electroluminescent element 100.

The anode layer 220 is located at a side of the hole transport layer 130 away from the green light-emitting layer 110 in the electroluminescent element 100.

In the embodiments of the present disclosure, the anode layer 220 is configured to provide holes to the electroluminescent element 100 and the cathode is configured to provide electrons to the electroluminescent element 100. Under the effect of an electric field, the holes migrate through the hole transport layer 130 to the green light-emitting layer 110 of the electroluminescent element 100 and the electrons migrate through the electron transport layer 120 to the green light-emitting layer 110 of the electroluminescent element 100, and meet in the green light-emitting layer 110 to generate energetic excitons, so as to excite light-emitting molecules to generate visible light.

In the embodiments of the present disclosure, the display panel 200 includes the above-mentioned electroluminescent elements 100, so the principles and technical effects thereof may refer to those mentioned hereinabove and will thus not be particularly defined herein.

Based on a same inventive concept, the present disclosure further provides in some embodiments a display device including the above-mentioned electroluminescent elements 100.

The display device is any product or member having a display function, such as television, digital photo frame, mobile phone, smart watch or tablet computer.

In the embodiments of the present disclosure, the display device includes the above-mentioned display panel 200, so the principles and technical effects thereof may refer to those mentioned hereinabove and will thus not be particularly defined herein.

Based on a same inventive concept, the present disclosure further provides in some embodiments a display device including the above-mentioned display panel 200.

The display device is any product or member having a display function, such as television, digital photo frame, mobile phone, smart watch or tablet computer.

In the embodiments of the present disclosure, the display device includes the above-mentioned display panel 200, so the principles and technical effects thereof may refer to those mentioned hereinabove and will thus not be particularly defined herein.

The following description will be given through comparing two electroluminescent elements.

### EXAMPLE 1

P1 is used as the hole-type host material. An HOMO energy level of P1 is 5.45 eV, an LUMO energy level is 2.15 eV, and its hole mobility μh=2.8*10⁻⁷ cm²/v·s.

N1 is used as the electron-type host material. An HOMO energy level of N1 is 5.62 eV, an LUMO energy level is 2.33 eV, and its electron mobility μe=7. 6*10⁻⁶ cm²/v·s.

A mass ratio of P1 to N1 is 6:4.

GD is used as the green guest light-emitting material, an HOMO energy level of GD is 5.15 eV, and an LUMO energy level is 2.72 eV.

A difference between the HOMO energy level of P1 and the HOMO energy level of GD is Δ HOMO_{P-GD}=0.30 eV, and a difference between the LUMO energy level of N1 and the LUMO energy level of the green guest light-emitting is Δ LUMO_{N-GD}=0.39 eV.

### Comparative Example 1

P2 is used as the hole-type host material. An HOMO energy level of P2 is 5.43 eV, an LUMO energy level is 2.03 eV, and its hole mobility μh=1.6*10⁻⁷ cm²/v·s.

N2 is used as the electron-type host material. An HOMO energy level of N2 is 5.84 eV, an LUMO energy level is 2.54 eV, and its electron mobility μe=6. 4*10⁻⁶ cm²/v·s.

A mass ratio of P2 to N2 is 4:6.

GD is also used as the green guest light-emitting material, an HOMO energy level of GD is 5.15 eV, and an LOMO energy level is 2.72 eV.

A difference between the HOMO energy level of P1 and the HOMO energy level of GD is Δ HOMO_{P-GD}=0.28 eV, and a difference between the LUMO energy level of N1 and the LUMO energy level of the green guest light-emitting is Δ LUMO_{N-GD}=0.18 eV.

P1 is 9,9′-di ([[1,1′-biphenyl]-4-yl)-9H, 9′H-3,3′-bicarbazole, with a chemical formula as shown in FIG. 4.

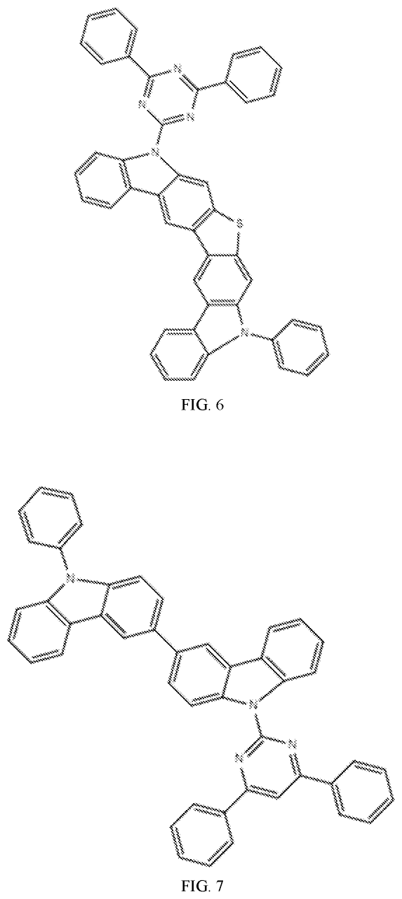

P2 is 9-([1,1′-biphenyl]-3-yl)-9′-([[1,1′-biphenyl]-4-yl]-9H, 9′H-3,3′-bicarbazole, with a chemical formula as shown in FIG. 5.

N1 is 5-(4,6-diphenyl-1,3,5-triazin-2-yl)-9-phenyl-5, 9-dihydrothieno [2,3-b: 5,4-b′] dicarbazole, with a chemical formula as shown in FIG. 6.

N2 is 9-(4,6-diphenylpyrimidin-2-yl)-9′-phenyl-9H, 9′H-3,3′-bicarbazole, with a chemical formula as shown in FIG. 7.

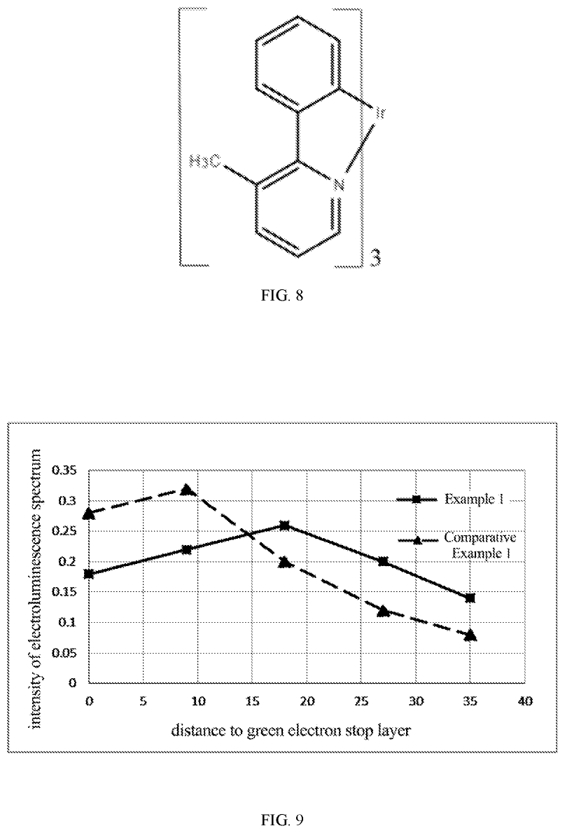

Gd is an iridium 3-methyl-2-phenylpyridine metal complex, with a chemical formula as shown in FIG. 8.

Structural parameters of the elements in Example 1 and Comparative Example 1 are shown in Table 1.

TABLE 1

| | Light-emitting layer |
|---|---|
| Example 1 | A thickness of the green light-emitting layer is 35 nm, a mass |
| | ratio of P1 to N1 is 6: 4, and a mass percentage of GD is 10%. |
| Comparative | A thickness of the green light-emitting layer is 35 nm, a mass |
| Example 1 | ratio of P1 to N1 is 4: 6, and a mass percentage of GD is 10%. |

Current voltage luminance (IVL) data of the elements in Example 1 and Comparative Example 1 are shown in Table 2:

TABLE 2

| | V(V) | Cd/A | CIE x | CIE y | LT95(h) |
|---|---|---|---|---|---|
| Example 1 | 100% | 100% | 0.25 | 0.72 | 100% |
| Comparative | 102% | 91% | 0.25 | 0.72 | 86% |
| Example 1 | | | | | |

In Table 2, V (V) represents voltage, Cd/A represents efficiency, CIE x represents a color coordinate, i.e., abscissa, CIE y represents another color coordinate, i.e., ordinate, and LT95 (h) represents a time taken for the attenuation of luminance to 95%, i. e. a service life.

FIG. 9 shows light-emitting effects of the exciton recombination region in Example 1 and Comparative Example 1. In FIG. 9, an abscissa represents a distance between the exciton recombination region and a green electron stop layer (or the hole transport layer), an ordinate represents an intensity of an exciton electroluminescence spectrum, “-▪-” represents a “distance-intensity” curve in Example 1, and “-▴-” represents a “distance-intensity” curve in Comparative Example 1. Obviously, as compared with Comparative Example 1, the exciton recombination region in Example 1 moves from the side of the green light-emitting layer 110 close to the hole transport layer 130 to the interior of the green light-emitting layer 110. As a result, it is able to not only weaken the triplet exciton annihilation effect but also enlarge the exciton recombination region, thereby to improve the luminous efficiency as well as the service life of the electroluminescent element.

The present disclosure at least has the following beneficial effects.

1. Through adjusting the ratio of hole mobility to electron mobility of the green light-emitting layer 110 as well as the ratio of energy level differences, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

2. Through adjusting the ratio of the hole mobility to the electron mobility of the green light-emitting layer to be not less than 1:100 and not more than 100:1, it is able to control the balance of the hole transport and the electron transport of the green light-emitting layer, so that the exciton recombination region moves from the side of the green light-emitting layer close to the hole transport layer to the interior of the green light-emitting layer. As a result, it is able to not only weaken the triplet exciton annihilation effect but also enlarge the exciton recombination region, thereby to improve the luminous efficiency as well as the service life of the electroluminescent element.

3. Through adjusting the hole mobility in the green light-emitting layer 110 to be not less than 1×10⁻⁸ cm²/v·s and not more than 1×10⁻⁴ cm²/v·s, it is able to control the balance between hole transport and electron transport in the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

4. Through adjusting the electron mobility in the green light-emitting layer 110 to be not less than 1×10⁻⁸ cm²/v·s and not more than 1×10⁻⁴ cm²/v·s, it is able to control the balance between hole transport and electron transport in the green light-emitting layer 110, o that the exciton recombination region moves from the side of the green light-emitting layer 110 close to the hole transport layer 130 to the interior of the green light-emitting layer 110. As a result, it is able to not only weaken the triplet exciton annihilation effect but also enlarge the exciton recombination region, thereby to improve the luminous efficiency as well as the service life of the electroluminescent element.

5. Through adjusting the HOMO energy level of the hole-type host material 111 in the green light-emitting layer 110 to be not less than 5.3 eV and not more than 5.8 eV, it is able to control the balance between hole transport and electron transport in the green light-emitting layer 110, so that the exciton recombination region moves from the side of the green light-emitting layer 110 close to the hole transport layer 130 to the interior of the green light-emitting layer 110. As a result, it is able to not only weaken the triplet exciton annihilation effect but also enlarge the exciton recombination region, thereby to improve the luminous efficiency as well as the service life of the electroluminescent element.

6. Through adjusting the HOMO energy level of the electron-type host material 112 to be not less than 5.5 eV and not more than 6.2 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

7. Through adjusting the LUMO energy level of the hole-type host material 111 be not less than 2.0 eV and not more than 2.5 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

8. Through adjusting the LUMO energy level of the electron-type host material 112 to be not less than 2.2 eV and not more than 2.7 eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

9. Through adjusting the HOMO energy level of the green light-emitting material 113 in the green light-emitting layer 110 to be not less than 4.8 eV and not more than 5.2 eV, it is able to control the balance between hole transport and electron transport in the green light-emitting layer 110, so that the exciton recombination region moves from the side of the green light-emitting layer 110 close to the hole transport layer 130 to the interior of the green light-emitting layer 110. As a result, it is able to not only weaken the triplet exciton annihilation effect but also enlarge the exciton recombination region, thereby to improve the luminous efficiency as well as the service life of the electroluminescent element.

10. Through adjusting the LUMO energy level of the green guest light-emitting material 113 to be not less than 2.4 eV and not more than 2.8 electron eV, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

11. Through adjusting the mass ratio of the hole-type host material 111 to the electron-type host material 112 to be not less than 1:1 and not more than 4:1 and adjusting the ratio of the first energy level difference to the second energy level difference to be not less than 1:4 and not more than 1:1, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

12. Through adjusting the ratio of the energy level differences between each of the hole-type host material 111 and the electron-type host material 112 and the green guest light-emitting material 113 to be not less than 1:1 and not more than 4:1, and adjusting the mass ratio of the hole-type host material 111 to the electron-type host material 112 to be not less than 1:4 and not more than 1:1, it is able to control the balance between the hole transport and the electron transport of the green light-emitting layer 110, so that the exciton recombination region moves from the side of the green light-emitting layer close to the hole transport layer 130 to the interior of the green light-emitting layer. As a result, it is able to not only weaken the triplet exciton annihilation effect but also enlarge the exciton recombination region, thereby to improve the luminous efficiency as well as the service life of the electroluminescent element.

It should be appreciated that, steps, measures and schemes in various operations, methods and processes that have already been discussed in the embodiments of the present disclosure may be replaced, modified, combined or deleted. In a possible embodiment of the present disclosure, the other steps, measures and schemes in various operations, methods and processes that have already been discussed in the embodiments of the present disclosure may also be replaced, modified, rearranged, decomposed, combined or deleted. In another possible embodiment of the present disclosure, steps, measures and schemes in various operations, methods and processes that are known in the related art and have already been discussed in the embodiments of the present disclosure may also be replaced, modified, rearranged, decomposed, combined or deleted.

It should be further appreciated that, such words as “center”, “on”, “under”, “front”, “back”, “left”, “right”, “vertical”, “horizontal”, “top”, “bottom”, “inner” and “outer” are used to indicate directions or positions as viewed in the drawings, and they are merely used to facilitate the description in the present disclosure, rather than to indicate or imply that a device or member must be arranged or operated at a specific position.

In addition, such words as “first” and “second” may merely be adopted to differentiate different features rather than to implicitly or explicitly indicate any number or importance, i.e., they may be adopted to implicitly or explicitly indicate that there is at least one said feature. Further, such a phrase as “a plurality of” may be adopted to indicate that there are two or more features, unless otherwise specified.

Unless otherwise specified, such words as “arrange” and “connect” may have a general meaning, e.g., the word “connect” may refer to fixed connection, removable connection or integral connection, or mechanical or electrical connection, or direct connection or indirect connection via an intermediate component, or communication between two components, or wired or wireless communication connection. The meanings of these words may be understood by a person skilled in the art in accordance with the practical need

In the above description, the features, structures, materials or characteristics may be combined in any embodiment or embodiments in an appropriate manner.

It should be further appreciated that, although with arrows, the steps in the flow charts may not be necessarily performed in an order indicated by the arrows. Unless otherwise defined, the order of the steps may not be strictly defined, i.e., the steps may also be performed in another order. In addition, each of at least parts of the steps in the flow charts may include a plurality of sub-steps or stages, and these sub-steps or stages may not be necessarily performed at the same time, i.e., they may also be performed at different times. Furthermore, these sub-steps or stages may not be necessarily performed sequentially, and instead, they may be performed alternately with the other steps or at least parts of sub-steps or stages of the other steps.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

What is claimed is:

1. An electroluminescent element, comprising an electron transport layer, a green light-emitting layer and a hole transport layer laminated one on another, wherein the green light-emitting layer comprises a hole-type host material, an electron-type host material and a green guest light-emitting material;
when a ratio of hole mobility of the hole-type host material to electron mobility of the electron-type host material is not greater than 1:1, a ratio of a first energy level difference to a second energy level difference is not greater than 1:1;
when the ratio of the hole mobility of the hole-type host material to the electron mobility of the electron-type host material is not less than 1:1, the ratio of the first energy level difference to the second energy level difference is not less than 1:1; and
the first energy level difference is a difference between a Highest Occupied Molecular Orbital (HOMO) energy level of the hole-type host material and an HOMO energy level of the green guest light-emitting material, and the second energy level difference is a difference between a Lowest Unoccupied Molecular Orbital (LUMO) energy level of the electron-type host material and an LUMO energy level of the green guest light-emitting material.

2. The electroluminescent element according to claim 1, wherein the ratio of the hole mobility of the hole-type host material to the electron mobility of the electron-type host material is not less than 1:100 and not greater than 100:1.

3. The electroluminescent element according to claim 1, wherein the hole mobility of the hole-type host material is not less than 1×10⁻⁸ cm²/v·s and not more than 1×10⁻⁴ cm²/v·s; or the electron mobility of the electron-type host material is not less than 1×10⁻⁸ cm²/v·s and not more than 1×10⁻⁴ cm²/v·s.

4. The electroluminescent element according to claim 1, wherein the hole mobility of the hole-type host material is not less than 1×10⁻⁸ cm²/v·s and not more than 1×10⁻⁴ cm²/v·s, and the electron mobility of the electron-type host material is not less than 1×10⁻⁸ cm²/v·s and not more than 1×10⁻⁴ cm²/v·s.

5. The electroluminescent element according to claim 1, wherein the HOMO energy level of the hole-type host material is not less than 5.3 eV and not more than 5.8 eV; or the HOMO energy level of the electron-type host material is not less than 5.5 eV and not more than 6.2 eV.

6. The electroluminescent element according to claim 1, wherein the HOMO energy level of the hole-type host material is not less than 5.3 eV and not more than 5.8 eV, and the HOMO energy level of the electron-type host material is not less than 5.5 eV and not more than 6.2 eV.

7. The electroluminescent element according to claim 1, wherein the LUMO energy level of the hole-type host material is not less than 2.0 eV and not more than 2.5 eV; or the LUMO energy level of the electron-type host material is not less than 2.2 eV and not more than 2.7 eV.

8. The electroluminescent element according to claim 1, wherein the LUMO energy level of the hole-type host material is not less than 2.0 eV and not more than 2.5 eV, and the LUMO energy level of the electron-type host material is not less than 2.2 eV and not more than 2.7 eV.

9. The electroluminescent element according to claim 1, wherein the HOMO energy level of the green guest light-emitting material is not less than 4.8 eV and not more than 5.2 eV; or the LUMO energy level of the green guest light-emitting material is not less than 2.4 eV and not more than 2.8 eV.

10. The electroluminescent element according to claim 1, wherein the HOMO energy level of the green guest light-emitting material is not less than 4.8 eV and not more than 5.2 eV, and the LUMO energy level of the green guest light-emitting material is not less than 2.4 eV and not more than 2.8 eV.

11. The electroluminescent element according to claim 1, wherein a mass ratio of the hole-type host material to the electron-type host material is not less than 1:1 and not more than 4:1, and the ratio of the first energy level difference to the second energy level difference is not less than 1:4 and not more than 1:1.

12. The electroluminescent element according to claim 11, wherein a ratio of the hole mobility of the hole-type host material to the electron mobility of the electron-type host material is not less than 1:100 and not more than 1:1.

13. The electroluminescent element according to claim 1, wherein a mass ratio of the hole-type host material to the electron-type host material is not less than 1:4 and not more than 1:1, and the ratio of the first energy level difference to the second energy level difference is not less than 1:1 and not more than 4:1.

14. The electroluminescent element according to claim 13, wherein the ratio of the hole mobility of the hole-type host material to the electron mobility of the electron-type host material is not less than 1:1 and not more than 100:1.

15. The electroluminescent element according to claim 1, wherein the hole-type host material comprises: a 9,9′-3,3′-bicarbazole unit containing a first substituent, and the first substituent comprises at least one of a substituted or unsubstituted C6 to C30 aryl group, a substituted or unsubstituted C2 to C30 heterocyclic group, and a substituted or unsubstituted C6 to C30 arylamine group.

16. The electroluminescent element according to claim 1, wherein the electron-type host material comprises an azine unit containing a second substituent, and the second substituent comprises at least one of hydrogen, deuterium, a substituted or unsubstituted C1 to C20 alkyl group, a substituted or unsubstituted C6 to C30 aryl group, a substituted or unsubstituted C2 to C30 heterocyclic group, a substituted or unsubstituted nitrile group, a substituted or unsubstituted isonitrile group, a substituted or unsubstituted hydroxyl group, and a substituted or unsubstituted thiol group.

17. The electroluminescent element according to claim 1, wherein the green guest light-emitting material comprises a diphenylpyridine iridium metal complex containing a third substituent, and the third substituent comprises at least one of hydrogen, an alkyl group, an alkenyl group, an alkynyl group, a heteroalkyl group, an alkenyl group, an alkynyl group, a heteroalkyl group, aryl group, a heteroaryl group, and an aralkyl group.

18. A display panel, comprising a cathode layer, an anode layer and the electroluminescent element according to claim 1, wherein the cathode layer is located at a side of the electron transport layer away from the green light-emitting layer in the electroluminescent element, and the anode layer is located at a side of the hole transport layer away from the green light-emitting layer in the electroluminescent element.

19. A display device, comprising the electroluminescent element according to claim 1.

20. A display device, comprising the display panel according to claim 18.
